(19) United States
(12) Patent Application Publication
(10) Pub. No.: US 2026/0293534 A1
(43) Pub. Date: Sep. 24, 2026

(54) SUPERCONDUCTING HARD-STOPS FOR FLIP CHIP

(71) Applicant: IQM FINLAND OY, Espoo (FI)

(72) Inventors: Mario PALMA, Espoo (ES); Máté JENEI, Espoo (ES); Jean-Luc ORGIAZZI, Espoo (ES); Hasnain AHMAD, Espoo (ES); Kuan TAN, Espoo (ES)

(21) Appl. No.: 19/480,190

(22) PCT Filed: Apr. 16, 2024
(86) PCT No.: PCT/FI2024/050173

§ 371 Date: Oct. 30, 2025

(30) Foreign Application Priority Data
May 10, 2023 (FI) 20235525

(51) Int. Cl. H10N 60/01; G06N 10/40; H10W 72/00

(52) U.S. Cl. CPC H10N 60/0912; H10W 72/07236; G06N 10/40

(57) ABSTRACT

The invention relates to the field of integrated circuit device fabrication, in particular to the fabrication of superconducting hard stops for flip chip devices. Superconducting hard stops are formed on a first substrate and are used to constrain the position of a second substrate relative to the first substrate.

### TECHNICAL FIELD

The invention relates to the field of integrated circuit device fabrication, in particular to the fabrication of superconducting hard stops for flip chip devices.

### BACKGROUND

Flip chip techniques may be used to manufacture superconducting quantum processors. In typical flip chip devices, the relative tilt of the bonded substrates is of the order of 100 μrads. The tilt angle causes a systematic drift in the total capacitance of the resonators and qubits, resulting in unwanted shift in the read-out spectrum. Maintaining a constant chip-to-chip distance throughout the whole device, i.e. minimising the relative tile, is necessary to manufacture high quality multi-qubit circuits and compact multiplexed readout structures.

### SUMMARY OF THE INVENTION

A first aspect of the invention is a method of fabricating a superconducting integrated circuit device. The method comprises
fabricating one or more superconducting qubits in a base layer on a first substrate;
forming a first resist over the base layer, the first resist comprising a plurality of first openings, each of the first openings exposing a different area of the base layer;
forming a seed layer over the first resist, the base layer and the first substrate such that the seed layer is in direct contact with the base layer within the first openings;
forming a second resist over the seed layer, the second resist comprising a plurality of second openings, each of the second openings exposing an area on the seed layer, wherein the second openings are positioned above the first openings;
depositing a superconducting hard stop on each exposed area of the seed layer by electroplating;
removing the first resist, second resist and seed layer except for areas of the seed layer between the superconducting metal hard stop and the base layer; and
forming a flip chip package by positioning a second substrate opposite the first substrate such that the second substrate or components thereon are in contact with the plurality of superconducting hard stops, wherein the position of the second substrate relative to the first substrate is constrained by the superconducting hard stops.

The seed layer may be formed by physical vapour deposition and may be performed at an angle offset from perpendicular to the surface of the first resist such that a portion of the sidewall or sidewalls of the first openings remain uncovered by the seed layer.

The seed layer may be formed by physical vapour deposition or chemical vapour deposition and may be performed at an angle perpendicular to the surface of the first resist such that less seed material is deposited on the sidewalls of the first openings than on the base layer, such that the deposited seed material on the sidewalls of the first openings permits solvent to penetrate to the first resist.

Sections of the seed layer in direct contact with the base layer may be electrically continuous with seed layer deposited on the surface of the first resist.

Depositing the superconducting hard stops by electroplating may comprise using the seed layer as a cathode such that the superconducting hard stop material is deposited on the sections of the seed layer that are exposed by the second openings in the second resist. The method may further comprise depositing a malleable superconducting cap on the superconducting hard stop exposed by the second openings prior to removing the first resist, second resist and seed layer. The malleable superconducting cap may be made of indium.

The superconducting hard stop may be made of rhenium.

The method may further comprise forming a plurality of flip chip bumps prior to forming a flip chip package.

Forming the flip chip package may further comprise reflowing the flip chip bumps.

A second aspect of the invention is a flip chip package. The flip chip package comprises one or more superconducting qubits in a base layer on a first substrate, a plurality of superconducting hard stops formed on the base layer, and a second substrate positioned opposite the first substrate. The second substrate or components thereon are in contact with the plurality of superconducting hard stops such that the position of the second substrate relative to the first substrate is constrained by the superconducting hard stops.

The superconducting hard stops may be made of rhenium.

The superconducting hard stops may further comprise a malleable superconducting cap. The malleable superconducting cap may be made of indium.

The superconducting hard stops may provide a superconductive connection between components on the first substrate and components on the second substrate.

A third aspect of the invention is a quantum computing system comprising the flip chip package manufactured according to the method described above, or the flip chip packages as described above.

### BRIEF DESCRIPTION OF THE DRAWINGS

FIG. 1 is a flow chart showing a method of forming a flip chip package according to the present invention.

FIGS. 2A-2G are schematic drawings at various stages of forming a flip chip package according to the method of claim 1.

### DETAILED DESCRIPTION OF THE INVENTION

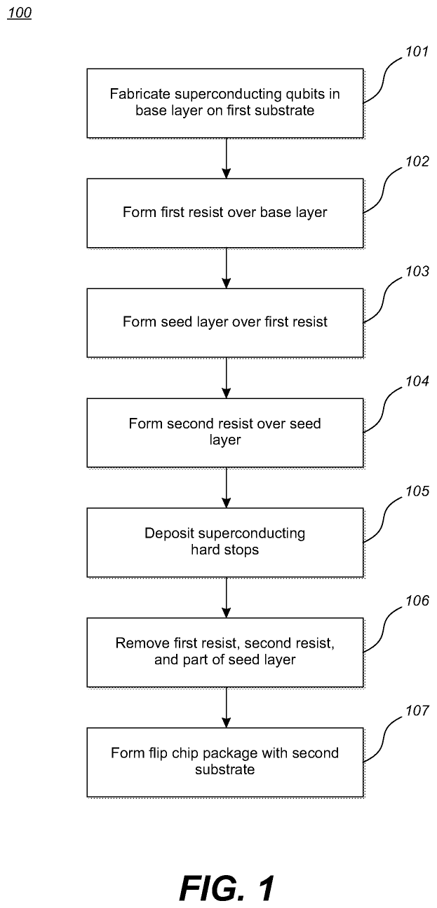

FIG. 1 shows a method 100 of forming a flip chip package that includes at least one superconducting qubit and a plurality of superconducting hard stops, which may be used to accurately, consistently, and reliably align the bonded substrates in the flip chip package. As a result, the electric properties, such as capacitance, of components formed on the bonded substrates are consistent, leading to improve qubit performance and improved readout performance compared with qubits formed in flip chip packages without the hard stops of the present invention. In this context, a hard stop is a mechanical element that limits movement of one chip or substrate in a flip chip package relative to the other in at least one direction.

Furthermore, the method 100 of the present invention is particularly suited to the formation of the hard stops after the qubit has been fabricated. Superconducting qubits and the components that make up the qubits, such as Josephson junctions, are particularly fragile and sensitive, thus further processing after fabrication of the qubits can easily lead to degradation of qubit properties and performance if the process steps and conditions are too harsh.

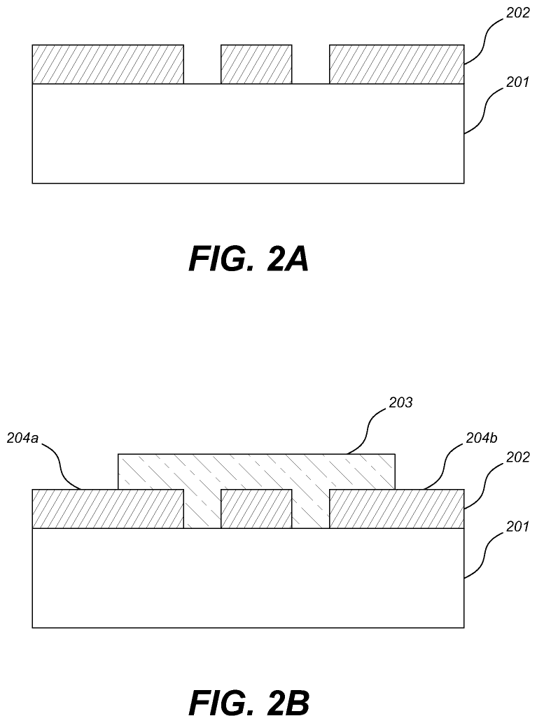

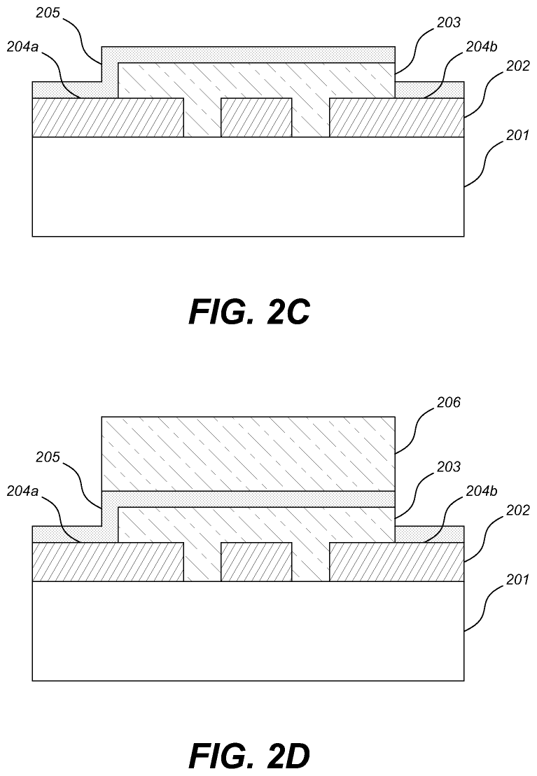

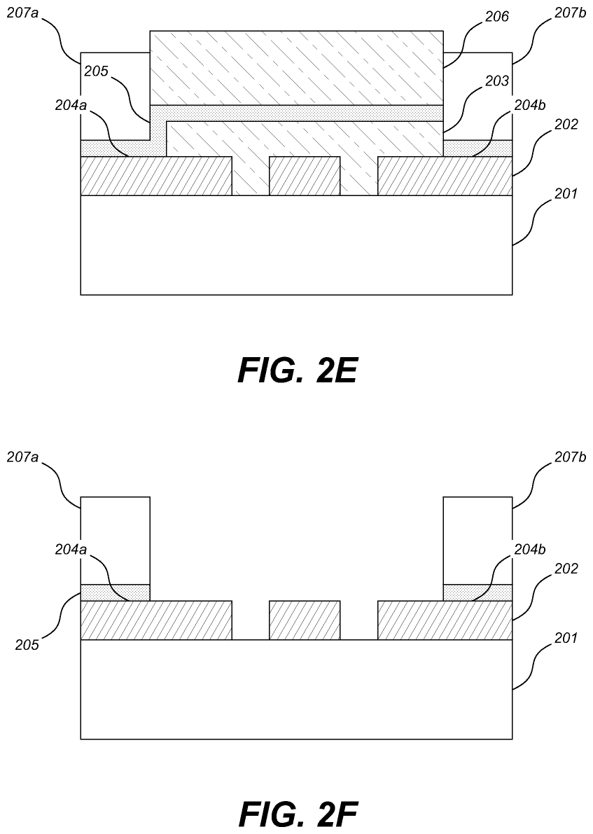

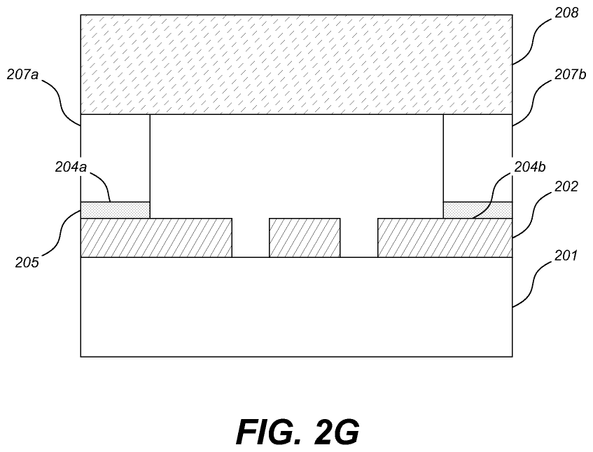

The method 100 includes step 101 of fabricating one or more superconducting qubits in a base layer on a first substrate. The result of step 101 is depicted in FIG. 2A, which depicts a substrate 201 and base layer 202. The substrate 201 may be silicone, sapphire or any other substrate on which is it possible to form superconducting qubits and which are suitable for use in a flip chip package. The superconducting qubit or qubits may be, for example, transmon qubits, as described in Koch, J. et al. Charge-insensitive qubit design derived from the Cooper pair box. Phys. Rev. A, 76(4), 042319 (2007 ), or unimon qubits as described in Hyyppä, E., Kundu, S., Chan, C.F. et al. Unimon qubit. Nat Commun 13, 6895 (2022). However, the advantages associated with the improved alignment of substrates in a flip chip package of the present invention are applicable to superconducting qubits of any kind, including combinations of different types of qubits. Furthermore, the advantages may be applicable to other types of superconducting circuits, or indeed in other applications where the distance between the substrates and the relative tilt of the substrates in a flip chip package should be carefully controlled. Thus, step 101 depicted in FIG. 1 is an optional step, that is the method of the present invention may not include a step of fabricating the superconducting qubits per se, but might be replaced by a step of fabricating another kind of circuit on the substrate. Step 101 may also be omitted from the method altogether, in which case the method may begin at step 102, described below, and a substrate with a suitable circuit already fabricated upon it may be used in the method.

At step 102, a first resist is formed over the base layer. The result of step 102 is shown in FIG. 2B, which depicts the first resist 203 in addition to the base layer 202 and substrate 201. As shown in FIG. 2B, the first resist includes first openings 204a, 204b, each of which exposes a different area of the base layer 202. The openings 204a, 204b are shown at the edges of the cross-section shown in FIG. 2B, but it will be appreciated that the openings may be formed at any suitable positions on the base layer, including at the edges of the resist 203 and thus only partially surrounded by the resist 203 and within the body of the resist 203 such that the openings are fully surrounded by the resist 203. The openings 204a, 204b in the first resist 203 may be positioned such that the exposed areas of the base layer 202 are contact pads or other connection points for forming electrical, possibly superconducting, connections between the components formed on the first substrate 201 and components, circuitry or wiring on a second substrate used in the flip chip package. The method of the present invention is particularly advantageous in that it can be used to form superconducting connections between the two substrates of the flip chip package while simultaneously performing the role of positioning and aligning the substrates. Alternatively, the exposed areas of the base layer may be electrically isolated parts of the base layer that are not electrically connected or used in the circuitry formed on the first substrate. In a further alternative, parts of the substrate 201 rather than the base layer 202 may be exposed by the openings in the first resist.

At step 103, a seed layer is formed over the first resist, the base layer and the first substrate. The result of step 103 is shown in FIG. 2C, which depicts the seed layer 205 in addition to the first resist 203, base layer 202 and substrate 201. Most superconducting films, which serve as base metal layer for circuit quantum electrodynamics, are not suitable for directly electroplating material, as performed in later steps of the method, due to alloy formation, bad adhesion, and high room-temperature resistivity for example. Additionally, the patterned films form islands of conductivity resulting in discontinuity in the conductive surface on which electroplating should occur. To prevent these issues, the seed layer is used. The seed layer acts as an adhesive and continuous conductive layer for electroplating. The seed layer is deposited such that the seed layer 205 is in direct contact with the base layer 203 within the first openings 204a, 204b. The seed layer may be deposited according the method described in European patent application publication No. EP 4 086 942 A2, which is incorporated by reference herein. In particular, the seed layer may be deposited by physical vapour deposition of the seed layer material using electron beam evaporation performed at an angle offset from perpendicular to the surface of the first resist 203 such that a portion of the sidewall or sidewalls of the openings in the first resist 203 remain uncovered by the seed layer. This advantageously allows the first resist to be removed using a suitable solvent, dependent on the resist material, at a later stage. Alternatively, physical vapour deposition may be performed at an angle perpendicular to the surface of the first resist 203 such that the seed layer material deposited on the sidewalls of the openings in the first resist 203 permits the solvent to penetrate to the first resist. Sections of the seed layer 205 in direct contact with the base layer 202 are electrically continuous with seed layer 205 deposited on the surface of the first resist 203.

In one example, the seed layer 205 is formed of two materials: titanium is used as an adhesion layer and copper as conducting layer. However, other variants are also possible, such as a titanium-tungsten adhesion layer and gold or titanium nitride as a conducting layer.

At step 104, a second resist is formed over the seed layer. The result of step 104 is shown in FIG. 2D, which depicts the second resist 206 in addition to the seed layer 205, first resist 203, base layer 202, and substrate 201. The second resist 206 includes second openings, each of which exposes an area on the seed layer above the areas 204a, 204b of the base layer 202 that are not covered by the first resist 203 or by a vertical section of the seed layer 205. In other words, the horizontal, i.e. parallel to the substrate, sections of the seed layer 205 that are in direct contact with the base layer 202 are exposed by the openings in the second resist 206.

At step 105, a superconducting hard stop is deposited on each exposed area of the seed layer. The result of step 105 is shown in FIG. 2E, which depicts the deposited superconducting hard stops 207a, 207b in addition to the second resist 206, seed layer 205, first resist 203, base layer 202 and substrate 201. The superconducting hard stops 207a, 207b are deposited on the exposed areas of the seed layer by electroplating. In particular, by using the seed layer as a cathode such that the superconducting hard stop material is deposited on the sections of the seed layer that are exposed by the second openings in the second resist 206. Preferably the superconducting hard stop material is rhenium. Rhenium is an extremely hard material and has Mohs class coefficient of 7 similar to that of Silicon. The hardness of rhenium makes it an ideal material for providing a hard stop, as it will not significantly deform during the flip-chip bonding process. In addition, rhenium is a paramagnetic, and superconducting material at low temperatures, thus it is compatible with high coherence superconducting devices such as qubits and quantum processing units.

In one example, the cathode (i.e. the package) and a non-reacting anode (typically platinum) are immersed in a solution containing sulfuric acid and rhenium salts. A well-defined potential difference between the cathode and anode will plate the exposed areas of the seed layer 205 with rhenium. The height of the hard stops 207a, 207b may be in the range of 1 to 20 microns. The height of the hard stops 207 a, 207 b may be at least 1 to 2 microns smaller than the combined height of the first resist 203 and second resist 206. For example. Thus, the height of the hard stops 207a, 207b may be controlled by controlling the parameters of the electroplating, such as the electrode voltage, electroplating solutions, exposure time, etc., and by controlling the height of the first resist 203 and second resist 206. Electroplating can be driven either by direct current (dc) or pulsed mode (ac).

As an alternative to rhenium, ruthenium may also be used as the material for the hard stops. Ruthenium is also a relatively hard material, i.e. it is harder than indium, which may be used to form superconducting flip chip bumps in the method of the present invention, and is superconducting.

Optionally, step 105 may further include the method depositing a malleable superconducting cap on the superconducting hard stop exposed by the second openings. Such a malleable superconducting cap may be formed of indium. Such a cap may allow for bonding of the first substrate with a second substrate positioned opposite via the hard stops 207a, 207b, e.g. by thermocompression bonding or reflowing the malleable superconducting material. If the height of the malleable superconducting cap is small enough relative to the height of the hard stops 207a, 207b, then the alignment of the second substrate relative to the first may not be significantly affected by variations in the final thickness of the malleable superconducting caps after flip chip bonding is performed. For example, the height of the malleable superconducting cap may be from 200-1000 nm.

At step 106, the first resist, second resist and part of the seed layer are removed. The result of step 106 is depicted in FIG. 2F, which shows the substrate 201, the base layer 202, the hard stops 207a, 207b and the parts of the seed layer 205 between the hard stops 207a and 207b and areas 204a and 204b of the base layer 202 that were exposed by the first openings in the resist. In other words, the parts of the seed layer 205 that were in direct contact with the base layer 202 remain after removal of the first resist 203, second resist 206 and other parts of the seed layer 205. Removal, or “lift off” of the first resist 203, second resist 206 and parts of the seed layer 205 may be performed by dissolving the resist material in a suitable solvent.

At step 107, a flip chip package may be formed by positioning a second substrate opposite the first substrate such that the second substrate (or components formed thereon) are in contact with the plurality of superconducting hard stops. In this way, the position (and alignment) of the second substrate relative to the first substrate is constrained by the superconducting hard stops. A schematic drawing of the result of step 107 is shown in FIG. 2G, in which a second substrate and any components formed thereon are represented by block 208. The position of block 208 relative to the first substrate 201 and components formed thereon, e.g. in the base layer 202, is constrained by the hard stops 207a and 207b. Components formed on the second substrate include circuitry, such as superconducting circuitry, which may be in electrical (possibly superconducting, when the device is below the critical temperature) connection with the components formed on the first substrate 201 via the hard stops 207a, 207b. Not shown in FIG. 2G are flip chip bumps, which may be used to bond the substrates and/or components on the substrates and may form further electrical (again, possibly superconducting) connections between the components formed on the first substrate and second substrate.

In addition to the method described above, the present invention also includes a flip chip package produced according to the method, i.e. a flip chip package as depicted in FIG. 2G.

In contrast to prior art methods the use silicon spacer posts to constrain the relative position of vertically bonded chips, the method of the present invention does not required abrasive substrate etching, which enables qubit-first, post-last fabrication without negatively affecting the properties of the already fabricated qubits. In addition, the method can be implemented for different substrate materials such as sapphire, which cannot be used in the prior art methods. Furthermore, where rhenium is used as the hard-stop material, its mechanical and chemical properties make it particularly suitable for hard-stop material, and as a paramagnetic superconducting material, microwave losses in the system are reduced compared to substrate-based hard posts.

1. A method of fabricating a superconducting integrated circuit device, the method comprising:
fabricating one or more superconducting qubits in a base layer on a first substrate;
forming a first resist over the base layer, the first resist comprising a plurality of first openings, each of the first openings exposing a different area of the base layer;
forming a seed layer over the first resist, the base layer and the first substrate such that the seed layer is in direct contact with the base layer within the first openings;
forming a second resist over the seed layer, the second resist comprising a plurality of second openings, each of the second openings exposing an area on the seed layer, wherein the second openings are positioned above the first openings;
depositing a superconducting hard stop on each exposed area of the seed layer by electroplating;
removing the first resist, second resist and seed layer except for areas of the seed layer between the superconducting hard stop and the base layer; and
forming a flip chip package by positioning a second substrate opposite the first substrate such that the second substrate or components thereon are in contact with the plurality of superconducting hard stops, wherein the position of the second substrate relative to the first substrate is constrained by the superconducting hard stops.

2. The method of claim 1, wherein the seed layer is formed by physical vapor deposition and is performed at an angle offset from perpendicular to the surface of the first resist such that a portion of the sidewall or sidewalls of the first openings remain uncovered by the seed layer.

3. The method of claim 1, wherein the seed layer is formed by physical vapor deposition or chemical vapor deposition and is performed at an angle perpendicular to the surface of the first resist such that less seed material is deposited on the sidewalls of the first openings than on the base layer, and wherein the deposited seed material on the sidewalls of the first openings permits solvent to penetrate to the first resist.

4. The method of claim 1, wherein sections of the seed layer in direct contact with the base layer are electrically continuous with seed layer deposited on the surface of the first resist.

5. The method of claim 4 wherein depositing the superconducting hard stops by electroplating comprises using the seed layer as a cathode such that the superconducting hard stop is deposited on the sections of the seed layer that are exposed by the second openings in the second resist.

6. The method of claim 1, wherein the method further comprises depositing a malleable superconducting cap on the superconducting hard stop exposed by the second openings prior to removing the first resist, second resist and seed layer.

7. The method of claim 6, wherein the malleable superconducting cap comprises indium.

8. The method of claim 1, wherein the superconducting hard stop comprises rhenium.

9. The method of claim 1, wherein the method further comprises forming a plurality of flip chip bumps prior to forming a flip chip package.

10. The method of claim 9, wherein forming the flip chip package further comprises reflowing the flip chip bumps.

11. A flip chip package comprising:
one or more superconducting qubits in a base layer on a first substrate;
a plurality of superconducting hard stops formed on the base layer;
a second substrate positioned opposite the first substrate, wherein the second substrate or components thereon are in contact with the plurality of superconducting hard stops such that the position of the second substrate relative to the first substrate is constrained by the superconducting hard stops.

12. The flip chip package of claim 11, wherein the superconducting hard stops comprise rhenium.

13. The flip chip package of claim 12, wherein the superconducting hard stops further comprise a malleable superconducting cap.

14. The flip chip package of claim 13, wherein the malleable superconducting cap comprises indium.

15. The flip chip package of claim 14, wherein the superconducting hard stops provide superconductive connections between components on the first substrate and components on the second substrate.

16. A quantum computing system comprising the flip chip package of claim 11.
